(19) United States
(12) Patent Application Publication
(10) Pub. No.: US 2014/0264733 A1
(43) Pub. Date: Sep. 18, 2014

(54) DEVICE WITH INTEGRATED PASSIVE COMPONENT

(71) Applicant: GLOBALFOUNDERIES SINGAPORE PTE. LTD., Singapore (SG)

(72) Inventors: Shaoning YUAN, Singapore (SG); Yue Kang LU, Singapore (SG); Yeow Kheng LIM, Singapore (SG); Juan Boon TAN, Singapore (SG); Soh Yun SIAH, Singapore (SG)

(73) Assignee: GLOBALFOUNDERS Singapore Pte. Ltd., Singapore (SG)

(21) Appl. No.: 13/802,835

(22) Filed: Mar. 14, 2013

(51) Int. Cl. H01L 49/02; H01L 21/768

(52) U.S. Cl. CPC H01L 28/10; H01L 21/76877
USPC 257/531; 438/675; 438/381

(57) ABSTRACT

Semiconductor devices and methods for forming a semiconductor device are presented. The semiconductor device includes a die which includes a die substrate having first and second major surfaces. The semiconductor device includes a passive component disposed below the second major surface of the die substrate. The passive component is electrically coupled to the die through through silicon via (TSV) contacts.

### CROSS-REFERENCE

This application cross-references to co-pending U.S. patent application Ser. No. 13/565,748, entitled “Device with Integrated Power Supply” (Attorney Docket Number GFSP2012NAT19US0), filed on Aug. 2, 2012, which is herein incorporated by reference for all purposes.

### BACKGROUND

As technology evolves into era of sub-micron, there is a desire to integrate different circuit elements into a single chip or integrated circuit (IC). There is also a desire to integrate different chips both vertically and horizontally in a single package to form a 2.5D or 3D IC package. Nevertheless, it is difficult to integrate these different types of elements in a single chip or a single package. Particularly, some of these elements may require large feature size for optimum or enhanced performance. For example, for RF applications, passive elements, such as high Q value inductors are required. However, the high Q value inductor is formed by ultra thick metal (UTM) process which introduces big feature size, such as >1.5 μm in width and >2 μm in thickness, in the front end of line (FEOL) or back end of line (BEOL) processes. This undesirably consumes a lot of chip space and chip thickness in these device levels. Moreover, such process is performed in the processing of advanced technode chips which is not cost effective.

From the foregoing discussion, it is desirable to provide a device with high circuit performance which requires reduced chip or package size. It is also desirable to provide a smaller product which enhances portability. In addition, it is desirable to provide a cost effective process for forming a device which is fully compatible with the process for forming 2.5D and 3D IC or package in the future.

### SUMMARY

Embodiments generally relate to semiconductor devices. In one embodiment, a semiconductor device is disclosed. In one embodiment, a semiconductor device is presented. The semiconductor device includes a die which includes a die substrate having first and second major surfaces. The semiconductor device includes a passive component disposed below the second major surface of the die substrate. The passive component is electrically coupled to the die through through silicon via (TSV) contacts.

In another embodiment, a method for forming a semiconductor device is disclosed. The method includes providing a die which includes a die substrate having first and second major surfaces. A passive component is provided below the second major surface of the die substrate. The passive component is electrically coupled to the die through through silicon via (TSV) contacts.

In yet another embodiment, a method for forming a semiconductor device is presented. The method includes providing a wafer having first and second major surfaces. A passive component is provided below the second major surface of the wafer. The passive component is electrically coupled to the wafer through through silicon via (TSV) contacts.

These and other advantages and features of the embodiments herein disclosed, will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. Various embodiments of the invention are described with reference to the following drawings, in which:

FIG. 1a shows a simplified cross-sectional view of an embodiment of a semiconductor device;

FIG. 1b shows enlarged view of a portion of the semiconductor device of FIG. 1a;

FIG. 1c shows a top view of an embodiment of an inductor;

FIG. 2 shows another embodiment of a semiconductor device;

FIGS. 3a-b show other embodiments of a semiconductor device; and

FIGS. 4-5 show flow charts of various embodiments of a process for forming a semiconductor device.

### DETAILED DESCRIPTION

Embodiments relate to semiconductor devices or integrated circuits (ICs). The semiconductor devices may include one or more dies. For the case of more than one die, the dies may be arranged in a planar arrangement, vertical arrangement, or a combination thereof. The die, for example, may include memory device, logic device, communication device, RF device, optoelectronic device, digital signal processor (DSP), microcontroller, system-on-chip (SOC) as well as other types of device or a combination thereof. Such semiconductor device may be incorporated into electronic products or equipment, such as phones, computers, mobile smart products, etc.

FIG. 1a shows a simplified cross-sectional view of an embodiment of a semiconductor device 100 while FIG. 1b shows simplified cross-sectional view of a portion A′ of the semiconductor device in greater detail. Referring to FIGS. 1a-b, the semiconductor device is a device package with a die 110. The die may be a singulated die. For example, a wafer is processed to have a plurality of dies. The processed wafer is diced to singulate the dies.

The die includes a die substrate 115. The die substrate may be a semiconductor substrate. For example, the die substrate may be a silicon substrate. Other types of semiconductor substrates may also be useful. For example, the die substrate may be a silicon-on-insulator, silicon germanium or other types of semiconductor substrates. The die substrate includes first and second major substrate surfaces 116a-b. The first major substrate surface 116a, for example, may be referred to as the front or active substrate surface and the second major surface 116b, for example, may be referred to as the back or inactive substrate surface. Other designations for the surfaces may also be useful.

The inactive substrate surface may serve as a bottom die surface 110b. The bottom die surface may be provided with a dielectric layer 170. The active surface is the surface of the substrate on which circuit components 140 are formed. The components, for example, include transistors having gate and source/drain (s/d) regions. Providing other types of circuit components may also be useful. For example, the substrate may include a combination of active and passive components.

A dielectric layer 131 is disposed over the components. The dielectric layer serves as a pre-metal dielectric (PMD) layer. The PMD layer, for example, includes silicon oxide, tetraethylorthosilicate (TEOS) or low-k dielectric. Other suitable types of dielectric material may also be used as the PMD layer. Typically, contacts 152 are provided through the PMD layer and are used to connect the front end devices, such as source/drain and gate of the transistor, to an interconnect metal layer disposed thereover. The contacts, for example, include tungsten contacts. Other suitable types of conductive materials can serve as contacts.

The components may be interconnected by interconnects 164 disposed on one or more metal levels 160. The metal levels, for example, are disposed over the PMD layer. A first metal level (e.g., M0) is disposed on the PMD layer. The first metal level includes interconnects 164 formed in an intra-metal dielectric (IMD) layer. The interconnects, for example, include copper or copper alloy interconnects. Other suitable types of conductive materials, such as Aluminum (Al), etc., may be used to form the interconnects.

Additional metal levels may be disposed over the first metal level. A metal level is formed in an interconnect dielectric (ICD) layer. An ICD layer 135, for example, includes lower and upper portions. The lower portion serves as an inter-level dielectric (ILD) layer while the upper portion serves as an intra-metal IMD layer. The IMD layer includes interconnects 164 of metal level Mx and the ILD includes via contact 162 of via level Vx, where x corresponds to a number of the metal level. For example, x is from 1 to the top metal level. Via contacts of via level Vx couples interconnects of Mx to interconnects of metal level Mx-1 below. Other configurations or designations of levels or layers may also be useful.

The ILD layer can be a single layer or a multi-layered dielectric stack. For example, a single layer can be used to serve as both the ILD and IMD or separate layers are used for the ILD and IMD. An etch stop layer may be provided between the ILD and IMD layers as well as between ICD layers. For multi-layered ICD, the ILD and IMD can include the same or different materials.

The dielectric material of the ICD may include a low-k (LK) or ultra low-k (ULK) dielectric material. Various types of low-k or ultra low-k materials, such as organo-silicate glass (OSG), fluorine-doped silicate glass (FSG) or SiCOH can be employed. Other types of dielectric materials are also useful. For example, the dielectric layer can include silicon oxide, doped silicon oxide such as fluorinated silicon oxide (FSG), undoped or doped silicate glasses such as boron phosphate silicate glass (BPSG) and phosphate silicate glass (PSG), undoped or doped thermally grown silicon oxide, undoped or doped TEOS deposited silicon oxide.

Die contact pads 168 are disposed over the ICD and are coupled to the interconnects in the metal levels. A passivation layer 137 having openings 171 is disposed over the ICD. As shown, the openings expose portions of the die contact pads. A top surface of the passivation layer, for example, may be referred to as a top die surface 110a. Under bump metallization and ball bumps (not shown) may be provided over the die contact pads, forming a flip chip.

The die, in one embodiment, includes a plurality of through silicon via (TSV) contacts 150. The TSV contacts are formed in through silicon vias (TSVs). The TSV contacts, for example, extend from the top surface of the PMD layer to the second major substrate surface 116b. The first surface 150a of the TSV contacts may be coupled to the die contact pads in the passivation layer via the interconnections through, for example, the ICD layers or metal levels. Other configurations of TSV contacts may also be useful. An insulating liner 157 may be provided to line the sidewalls of the TSVs. In some cases, the liner may also line the surface of the PMD. Other configurations of the liner may also be useful.

In one embodiment, a passive component/element 120 is integrated into the device package. The passive component, in one embodiment, includes an inductor. Other suitable types of passive components, such as transformers, may also be useful. For illustration purposes, an inductor is shown as the passive component. The inductor, in one embodiment, is disposed over the second major substrate surface 116b. In one embodiment, the inductor is disposed in a dielectric layer 170. For example, the inductor is disposed in a first plane or a metal level of the dielectric layer 170 disposed over the second major substrate surface 116b. The dielectric layer or liner separates the metal level from the substrate. FIG. 1c shows a top view of an exemplary inductor. The inductor, for example, includes metal trace forming first and second concentric loops 121 and 123. The loops include the geometric shape of an inductor circuit. The loops are separated by an interloop spacing 126.

The outer loop, for example, includes first and second segments 121a-b. The first and second segments are, for example, about the same length. Forming first and second segments having unequal lengths are also useful. The inner loop includes first and second ends, forming an open loop. The inductor includes first and second terminals 125a-b. The first and second terminals of the inductor are coupled to first ends of the outer segments. The second ends of the outer inductor segments are coupled to first and second ends of the inner loop via a cross-over coupling 127. The first ends are located on a first portion of the inductor circuit while the second ends are located on a second portion. The first and second portions are opposite portions of the inductor circuit.

The cross-over coupling, for example, is provided on a second plane of the dielectric layer which is different than first plane where the loops of the inductor are formed. For example, the cross-over coupling is provided on a plane below the inductor. Forming the cross-over coupling in a plane above the inductor is also useful.

The inductor, as described above, is for purpose of illustration and should not be limited thereto. The inductor may include other suitable types of configurations. For example, the inductor may be formed on multiple metal levels. It is also understood that the device package may include other types of inductor disposed over the second major substrate surface or inactive surface 116b of the die.

In one embodiment, the terminals 125a-b of the inductor disposed on the second substrate surface or backside of the die are directly coupled to the other components via some of the TSV contacts 150. In one embodiment, the terminals of the inductor are directly coupled to the second surfaces 150b of some of the TSV contacts as shown in FIGS. 1a-b. This enables the inductor to filter and remove spikes on power lines and for other suitable applications. The remaining TSV contacts 150, in one embodiment, are coupled to redistribution layers (RDLs) 181 which are disposed, for example, in the same plane or the same metal level as the inductor, in the dielectric layer 170 over the second substrate surface 116b. Under bump metallization 183 and ball bumps 185, for example, may be provided over the RDLs 181 as shown in FIG. 1a. In another embodiment, the terminals 125a-b of the inductor disposed on the second substrate surface or backside of the die are indirectly coupled to some of the TSV contacts 150 through metal traces or RDLs (not shown).

FIG. 2 illustrates another embodiment of a semiconductor device 200. The semiconductor device is similar to that described in FIGS. 1a-b. As such, common elements may not be described or described in detail. The semiconductor device 200, in one embodiment, includes a die stack. The die stack includes x number of dies, where x is ≧2. For example, the die stack includes dies 110₁₋ₓ. Illustratively, the die stack includes two dies, a bottom die 110₁ and a top die 110₂. Providing a die stack with other number of dies may also be useful. For die stacks with more than 2 dies, intermediate dies 110₂₋₍ₓ₋₁₎ are disposed between the top and bottom dies. The dies of the die stack can be of the same type and/or size. Providing a die stack having chips which are different types and/or sizes is also useful.

The dies, for example, include a combination of TSV contacts 150 which are coupled to terminals of the passive components 120, such as inductors, and TSV contacts 150 which are coupled to RDLs for die stacking. For example, the passive components are disposed on the bottom or the second substrate surface of the dies. The RDLs of a die provide connections to TSV contacts of a die below. For example, the RDL of the i^{th}+1 die provides connections to the TSV contacts of the i^{th} die. Moreover, it is understood that not all dies need to have the same configurations. For example, the bottom die may include a combination of TSV contacts which are used for connecting to the passive component as well as TSV contacts which are used for die stacking, while the other dies include TSV contacts which are coupled to RDLs for connecting an i^{th}+1 die to die pads of i^{th} die.

FIGS. 3a-b illustrate other embodiments of a semiconductor device 300. Referring to FIG. 3a, the semiconductor device 300 includes a passive device 120, such as inductor, integrated into a die. The die, for example, is a non-active die. In one embodiment, the device includes an inductor integrated into an interposer 380. The interposer serves as a support member for coupling an active die 310 to a package substrate 390. The interposer may be formed of, for example, silicon. Other suitable types of materials may also be used in forming the interposer.

The interposer includes first and second interposer surfaces 380a-b. A dielectric layer may line each of the first and second surfaces of the interposer. As shown, the passive device 120 is disposed on the second interposer surface 380a while the die is disposed on the first interposer surface. In one embodiment, the interposer includes interposer contacts 350 formed in through silicon vias formed in the interposer substrate. The interposer contacts 350, for example, are similar to the TSV contacts 150 described in FIGS. 1a-b. The interposer includes a combination of interposer contacts 350 which enable connections to the terminals 121a-b of the inductor 120 disposed on the second interposer surface to the die 310 disposed on the first interposer surface as well as interposer contacts 350 which are coupled to the RDLs 381 enabling electrical connection between the die 310 on top of the interposer 380 and the package substrate 390.

The die 310, for example, may include TSV contacts (not shown) which provide connections on its bottom surface 310b to die pads (not shown) which are coupled to RDLs (not shown) disposed on the top interposer surface 380a. RDLs may be disposed on the first and second major surfaces of the interposer, providing connections between the interposer contacts 350 to the TSV contacts (not shown) of the die 310 and the package substrate below 390.

As shown, a single die 310 is provided on the first major surface of the interposer. It is understood that a die stack, as described in FIG. 2, may be provided on the first interposer surface. For example, the dies of the die stack may be coupled to the interposer contacts by TSV contacts. In other embodiments, the dies may be coupled by TSV contacts while the top die of the die stack is coupled to the interposer contacts by interconnect metal layers and bump connections 315.

In an alternative embodiment, as shown in FIG. 3b, a plurality of dies are disposed on the first interposer surface. For example, m number of dies may be disposed in a non-stacked configuration. Illustratively, two dies 410₁₋₂ (e.g., m=2) are disposed on the first interposer surface 380a. The dies may be coupled to the passive device 120, such as inductor, by some of the TSV contacts 350. In one embodiment, the dies may include non-TSV type of dies. In such embodiments, the dies are coupled to the interposer contacts by bump connections 315. The dies, in another embodiment, include TSV type of dies. Other configurations of dies may also be useful. In some embodiments, the device may include die stacks, as described in FIGS. 2 and 3a, disposed on the first interposer surface. Also, providing a combination of die stacks and dies on the first interposer surface may also be useful.

As described, the die or a set of dies is provided with TSV contacts. The TSV contacts enable the passive component 120, such as an inductor with high Q value with big feature size, to be disposed on the back or second substrate surface. The TSV contacts, in one embodiment, enables coupling of the inductor which is disposed on the second substrate surface to the circuit components on the first substrate surface. Moreover, the remaining TSV contacts also enable coupling to the RDLs for chip stacking or for connection to the package substrate. Since the inductor is coupled to the back or second surface of the substrate, capacitance and crosstalk concern is reduced. Such configuration also avoids the use of an additional shield, reducing the cost of production.

FIG. 4 shows a flow chart illustrating an embodiment of a process for forming a semiconductor device 400. The process includes providing a wafer, such as a large scale integration (LSI) wafer, being processed at step 410. The wafer, in one embodiment, includes a TSV type of die similar or the same as that described with respect to FIGS. 1a-b above. As such, common elements may not be described or described in detail. For example, the wafer is prepared with through silicon vias (TSVs). The wafer includes a wafer substrate having first (active) and second (inactive) major surfaces. The die, for example, includes a circuit component or a plurality of circuit components formed on the first or active surface of the die substrate. In one embodiment, the die includes a plurality of through silicon via (TSV) contacts formed in through silicon vias (TSVs) within the die substrate. The TSVs, for example, may be formed by deep reactive ion etching (DRIE) or laser drilling process. Other suitable techniques may also be used to form the TSVs. Insulation liners, for example, may be formed to line the sidewalls of the TSVs. The TSVs, in one embodiment, are filled by conductive material, such as copper (Cu), by electroplating process and are planarized using chemical mechanical polishing (CMP) to form the TSV contacts. Other suitable techniques and materials may also be used to form the TSV contacts.

The process continues by thinning the second surface or inactive surface of the wafer to reduce the thickness of the wafer. The second surface of the wafer, for example, is thinned by processes such as grinding, CMP, RIE, etc., or a combination thereof. The backgrinding process, for example, exposes the bottom of the TSV contacts at step 412.

At step 414, a passive component and RDLs are formed on the second major surface of the wafer. The passive component, in one embodiment, includes an inductor. Providing other types of passive component may also be useful. For illustration, the passive component includes an inductor similar to that described with respect to FIG. 1c. As such, features of the inductor may not be described or described in detail. It is understood that other types of inductors may also be useful. In one embodiment, the inductor is integrally formed or built on the second major surface of the wafer. The inductor, for example, is simultaneously formed with the RDLs on the second major surface of the wafer. The process includes electrically coupling the inductor and the circuit components on the first or active surface of the wafer directly or indirectly through some of the TSV contacts while the other TSV contacts are coupled to the RDLs at step 414.

The process may include further or additional processing steps to complete the fabrication of the semiconductor device. For example, the wafer can be diced or singulated to separate the wafer into individual dies with integrated passive component, such as inductor, and further processed to form a device package as shown in FIG. 1a-b at step 416. The process, in other embodiments, may further include mounting additional die or dies on top of the singulated die to form a die stack with integrated inductors as shown in FIG. 2.

As described, the TSV contacts enable the passive component, such as an inductor with high Q value having big feature size, to be disposed on the back or second substrate surface. The TSV contacts, in one embodiment, enables coupling of the inductor which is disposed on the second substrate surface to the circuit components on the first substrate surface. As such, the process of forming the passive component, such as the inductor with high Q value, can be separated from other front end of line (FEOL) and back end of line (BEOL) processes. This enables the inductor having big feature size to be processed in low technode fab or outsourced semiconductor assembly and test. Moreover, the remaining TSV contacts also enable coupling to the RDLs for chip stacking or for connection to a package substrate. Since the inductor is coupled to the back or second surface of the substrate, capacitance and crosstalk concern is reduced. Such configuration also avoids the use of an additional shield, reducing the cost of production. In addition, the embodiment as described with respect to FIG. 4 is a fully compatible process with the process of forming 3D ICs or package in the future.

FIG. 5 shows a flow chart illustrating another embodiment of a process for forming a semiconductor device 500. The process includes providing a wafer having first and second major surfaces. The wafer, in one embodiment, serves as an interposer wafer at step 510. The interposer wafer, in one embodiment, includes a silicon wafer having a plurality of interposer contacts. The interposer contacts, for example, are similar to the TSV contacts as described in FIG. 4. The interposer contacts, for example, may be formed by similar process as described for the TSV contacts of FIG. 4. As such, common elements may not be described or described in detail.

The second or bottom surface of the interposer wafer is thinned to reduce the thickness of the wafer. The second surface of the interposer wafer, for example, is thinned by processes such as grinding, CMP, RIE, etc., or a combination thereof. The backgrinding process, for example, exposes the bottom of the interposer contacts at step 512.

At step 514, a passive component and RDLs are provided on the second major surface of the interposer wafer. The passive component includes an inductor similar to that described with respect to FIG. 1c. It is understood that other types of inductors may also be useful. In one embodiment, the inductor is integrally formed or built on the second major surface of the interposer wafer. The inductor, for example, is simultaneously formed with the RDLs on the second major surface of the interposer wafer.

The process also includes providing a die or a plurality of dies at step 514 on the first surface of the interposer wafer. In one embodiment, the die may include TSV type of die similar or the same as that described with respect to FIGS. 1a-b above. In other embodiments, the die may include non-TSV type of die. The die or the plurality of dies having TSV contacts are mounted on the first major surface of the interposer wafer. The process includes electrically coupling the passive component and the die or dies through some of the interposer contacts of the interposer wafer at step 514.

The process may include further or additional processing steps to complete the fabrication of the semiconductor device. For example, the interposer wafer can be diced or singulated to separate the wafer and further processed to form the individual device package with integrated passive component, such as inductor, as shown in FIG. 3a-b at step 516. The process, in other embodiments, may also include mounting additional die or dies on top of the device package to form a die stack device package with integrated passive components.

The embodiment as described with respect to FIG. 5 includes some or all advantages as described with respect to FIG. 4. As such, these advantages will not be described or described in detail. Furthermore, the embodiment as described with respect to FIG. 5 is a fully compatible process with the process of forming 2.5D ICs or package in the future.

The invention may be embodied in other specific forms without departing from the spirit or essential characteristics thereof. The foregoing embodiments, therefore, are to be considered in all respects illustrative rather than limiting the invention described herein. Scope of the invention is thus indicated by the appended claims, rather than by the foregoing description, and all changes that come within the meaning and range of equivalency of the claims are intended to be embraced therein.

What is claimed is:

1. A semiconductor device comprising:
a die which includes a die substrate having first and second major surfaces; and
a passive component disposed below the second major surface of the die substrate, wherein the passive component is electrically coupled to the die through through silicon via (TSV) contacts.

2. The semiconductor device of claim 1 wherein the TSV contacts are disposed within the die substrate.

3. The semiconductor device of claim 2 wherein the first major surface is an active substrate surface while the second major surface is an inactive substrate surface.

4. The semiconductor device of claim 3 wherein circuit components are disposed on the first major surface.

5. The semiconductor device of claim 2 wherein:
the passive component includes an inductor having at least first and second terminals; and
the TSV contacts are coupled to the first and second terminals.

6. The semiconductor device of claim 5 wherein the inductor directly contacts the second major surface of the die substrate.

7. The semiconductor device of claim 1 wherein the die is an interposer die.

8. The semiconductor device of claim 7 wherein the TSV contacts are disposed within the interposer.

9. The semiconductor device of claim 7 comprising a die being disposed on a first interposer surface while the passive component is disposed on a second interposer surface.

10. The semiconductor device of claim 9 wherein the die is coupled to the interposer by TSV contacts within the die substrate or bump connections on the first interposer surface.

11. A method for forming a semiconductor device comprising:
providing a die which includes a die substrate having first and second major surfaces; and
providing a passive component below the second major surface of the die substrate, wherein the passive component is electrically coupled to the die through through silicon via (TSV) contacts.

12. The method of claim 11 comprises forming the TSV contacts within the die substrate.

13. The method of claim 11 wherein the die is an interposer die.

14. The method of claim 13 comprises forming the TSV contacts within the interposer.

15. A method for forming a semiconductor device comprising:
providing a wafer having first and second major surfaces; and
providing a passive component below the second major surface of the wafer, wherein the passive component is electrically coupled to the wafer through through silicon via (TSV) contacts.

16. The method of claim 15 wherein the wafer is processed with a plurality of dies having circuit components on the first major surface of the wafer.

17. The method of claim 16 comprises:
forming TSV contacts within the wafer; and
thinning the second major surface of the wafer to expose bottom surfaces of the TSV contacts.

18. The method of claim 17 wherein providing the passive component comprises integrally forming an inductor on the second major surface of the wafer.

19. The method of claim 15 wherein:
the wafer serves as an interposer wafer, and comprises
forming the TSV contacts within the interposer wafer.

20. The method of claim 19 further comprises providing a die or dies on the first major surface of the interposer wafer.
